(19) United States
(12) Patent Application Publication
(10) Pub. No.: US 2016/0218062 A1
(43) Pub. Date: Jul. 28, 2016

(54) THIN FILM RESISTOR INTEGRATION IN COPPER DAMASCENE METALLIZATION

(71) Applicant: Texas Instruments Incorporated, Dallas, TX (US)

(72) Inventors: Rajni J. Aggarwal, Garland, TX (US); John P. Campbell, Dallas, TX (US); Kaiping Liu, Plano, TX (US); Weidong Tian, Dallas, TX (US)

(73) Assignee: TEXAS INSTRUMENTS INCORPORATED, Dallas, TX (US)

(21) Appl. No.: 14/604,660

(22) Filed: Jan. 23, 2015

(51) Int. Cl. H01L 23/522; H01L 23/532; H01L 23/31; H01L 49/02; H01L 21/768; H01L 21/02; H01L 21/285; H01L 21/321; H01L 23/528; H01L 23/29

(52) U.S. Cl. CPC H01L 23/5228; H01L 23/5226; H01L 23/528; H01L 23/53228; H01L 23/3157; H01L 23/291; H01L 23/53266; H01L 21/76802; H01L 21/76877; H01L 21/02164; H01L 21/28568; H01L 21/3212; H01L 28/24

(57) ABSTRACT

An integrated circuit with copper damascene interconnects includes a thin film resistor. Copper damascene metal lines are formed in a first ILD layer. A dielectric layer including an etch stop layer is formed on the first ILD layer and metal lines. Resistor heads of refractory metal are formed in the dielectric layer so that edges of the resistor heads are substantially coplanar with the adjacent dielectric layer. A thin film resistor layer is formed on the dielectric layer, extending onto the resistor heads. A second ILD layer is formed over the dielectric layer and the thin film resistor layer. Copper damascene vias are formed in the second ILD layer, making contact to the metal lines in the first ILD layer. Connections to the resistor heads are provided by the metal lines and/or the vias.

### FIELD OF THE INVENTION

This invention relates to the field of integrated circuits. More particularly, this invention relates to thin film resistors in integrated circuits.

### BACKGROUND OF THE INVENTION

Some integrated circuits with copper damascene interconnects include a thin film resistor. Integrating the resistor in the integrated circuit fabrication process requires forming reliable, low resistance connections between the resistor heads and the thin film resistor body, and forming connections to the resistor heads. Integrating such a thin film resistor has typically required three additional photolithography operations, one each for the heads, body and connections to the heads, undesirably increasing fabrication cost and complexity of the integrated circuit.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

An integrated circuit with copper damascene interconnects includes a thin film resistor. Copper damascene metal lines are formed in a first ILD layer. A dielectric layer including an etch stop layer is formed on the first ILD layer and metal lines. Resistor heads of refractory metal are formed in the dielectric layer so that edges of the resistor heads are substantially coplanar with the adjacent dielectric layer. A thin film resistor layer is formed on the dielectric layer, extending onto the resistor heads. A second ILD layer is formed over the dielectric layer and the thin film resistor layer. Copper damascene vias are formed in the second ILD layer, making contact to the metal lines in the first ILD layer. Connections to the resistor heads are provided by the metal lines and/or the vias.

### DESCRIPTION OF THE VIEWS OF THE DRAWING

FIG. 1 is a cross section of an example integrated circuit containing a thin film resistor.

FIG. 2A through FIG. 2K are cross sections of the integrated circuit of FIG. 1 depicted in successive stages of fabrication.

FIG. 3 is a cross section of another example integrated circuit containing a thin film resistor.

FIG. 4A through FIG. 4G are cross sections of the integrated circuit of FIG. 3 depicted in successive stages of fabrication.

FIG. 5A through FIG. 5D are cross sections of another example integrated circuit containing a thin film resistor, depicted in successive stages of fabrication.

FIG. 6 is a top view of an example integrated circuit containing a thin film resistor.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

An integrated circuit with copper damascene interconnects, that is metal lines and vias, may be formed to include a thin film resistor using only two photolithographic operations to integrate the thin film resistor. Resistor heads are formed of a refractory metal by a damascene process in a dielectric layer over a first inter-level dielectric (ILD) layer containing a level of copper damascene metal lines. A thin film resistor body is formed on the dielectric layer, extending onto the resistor heads. A second ILD layer is formed over the thin film resistor and copper damascene vias are formed in the second ILD layer, making connections to the copper damascene metal lines in the first ILD layer. Connections to the resistor heads are provided by instances of the copper damascene metal lines in the first ILD layer and/or the copper damascene vias in the second ILD layer.

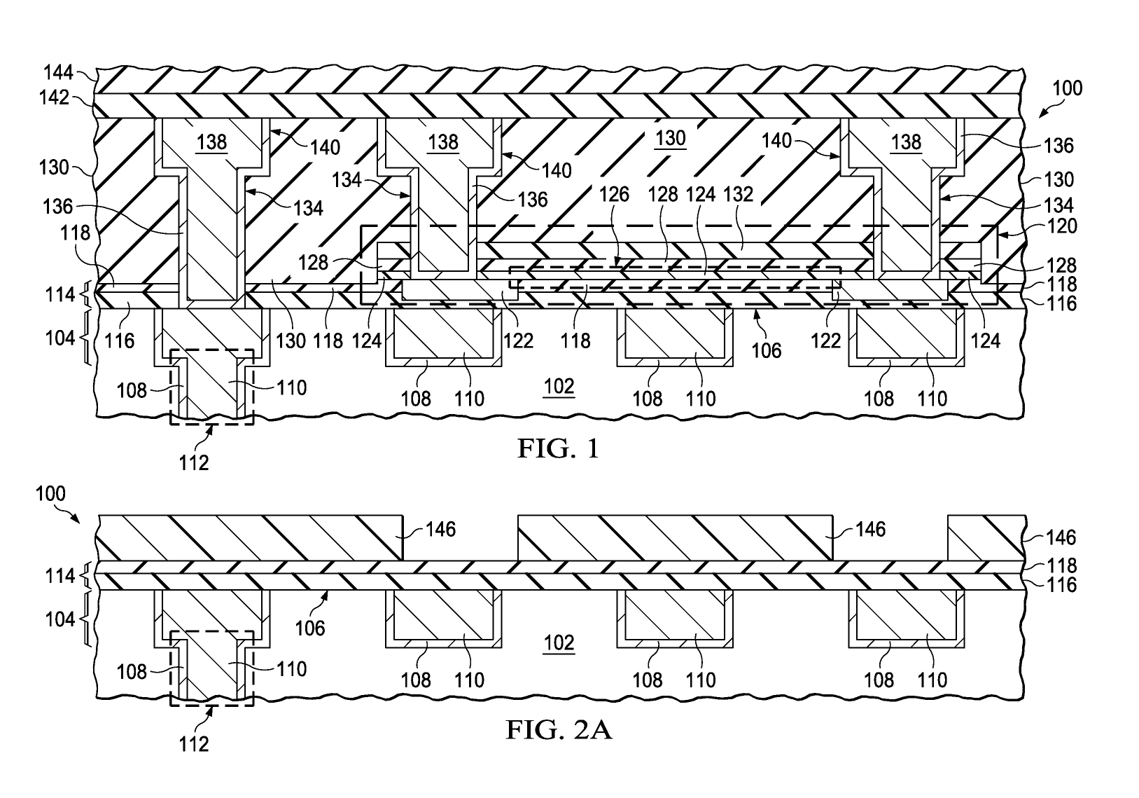

FIG. 1 is a cross section of an example integrated circuit containing a thin film resistor. The integrated circuit 100 includes a first ILD layer 102 of silicon dioxide-based material, such as fluorosilicate glass (FSG) or organosilicate glass (OSG). A plurality of first metal lines 104 having copper damascene structures are disposed in the first ILD layer 102, extending to a top surface 106 of the first ILD layer 102. Each instance of the first metal line 104 includes a refractory metal liner 108 of tantalum and/or tantalum nitride, and a fill metal 110 of copper on the metal liner 108. One or more of the first metal lines 104 may be connected to first vias 112 having copper damascene structures, disposed in the first ILD layer 102. The first metal lines 104 and first vias 112 may be dual damascene structures as depicted in FIG. 1, or may be single damascene structures. The first metal lines 104 may be in a first interconnect level of the integrated circuit 100, or may be in a higher interconnect level, such as a second interconnect level, a third interconnect level, and so forth.

A dielectric layer 114 is disposed on the first ILD layer 102 and on the first metal lines 104. The dielectric layer 114 is less than 200 nanometers thick. The dielectric layer 114 includes an etch stop layer 116 over the first metal lines 104. The etch stop layer 116 may be primarily silicon nitride-based dielectric material, 50 nanometers to 100 nanometers thick, which advantageously reduces copper migration from the first metal lines 104. The dielectric layer 114 may include a resistor backside passivation layer 118 over the etch stop layer 116. The resistor backside passivation layer 118 is a dielectric sub-layer and may be primarily silicon dioxide-based dielectric material, 15 nanometers to 100 nanometers thick, which advantageously provides desired adhesion and electrical properties for the thin film resistor 120.

Resistor heads 122 of the thin film resistor 120 are disposed in the dielectric layer 114, so that edges of the resistor heads 122 are substantially coplanar with the adjacent dielectric layer 114. The resistor heads 122 comprise refractory metal, for example tantalum, tantalum nitride, or a stack of tantalum and tantalum nitride. The resistor heads 122 may comprise a composition and layer structure similar to the metal liner 108 of the first metal lines 104, which may advantageously reduce complexity and cost of the integrated circuit 100. The resistor heads 122 may be confined to the resistor backside passivation layer 118, or may extend into the etch stop layer 116 as depicted in FIG. 1.

A thin film resistor layer 124 is disposed on the dielectric layer 114, extending onto the resistor heads 122. The thin film resistor layer 124 between the resistor heads 122 provides a resistor body 126 of the thin film resistor 120. The thin film resistor layer 124 may include any appropriate thin film resistor material, such as silicon chromium, silicon carbon chromium, and/or nickel chromium. The thin film resistor layer 124 is less than 15 nanometers thick, and may be, for example, 2 nanometers to 5 nanometers thick. The thin film resistor layer 124 may extend past the resistor heads 122 on all sides as depicted in FIG. 1 or may extend only partway onto the resistor heads 122.

A resistor topside passivation layer 128 may be disposed on the thin film resistor layer 124. The resistor topside passivation layer 128 is a dielectric sub-layer and may have a composition similar to the resistor backside passivation layer 118 which advantageously enhances electrical performance of the thin film resistor 120. The resistor topside passivation layer 128 does not extend substantially past the thin film resistor layer 124. The resistor topside passivation layer 128 may be thinner than the resistor backside passivation layer 118, for example 5 nanometers to 15 nanometers thick; the resistor backside passivation layer 118 and the etch stop layer 116 are thick enough to provide a desired thickness for the resistor heads 122, while minimizing the thickness of the resistor topside passivation layer 128 advantageously reduces non-planarity in a subsequently-formed second ILD layer 130. The resistor topside passivation layer 128 may be substantially coterminous with the thin film resistor layer 124, as depicted in FIG. 1.

An optional resistor etch stop 132 may be formed over the thin film resistor layer 124 and over the resistor topside passivation layer 128 if present. The resistor etch stop 132 may have a composition similar to the etch stop layer 116. The resistor etch stop 132 may be 10 percent to 20 percent thicker than the etch stop layer 116 to provide desired etch stop performance during a subsequent via etch process. The resistor etch stop 132 may be substantially coterminous with the thin film resistor layer 124, as depicted in FIG. 1. The resistor backside passivation layer 118 may be thinner outside of the thin film resistor 120 compared to under the thin film resistor layer 124, as depicted in FIG. 1, due to erosion of the resistor backside passivation layer 118 during etching of the thin film resistor layer 124, the resistor topside passivation layer 128 and the resistor etch stop 132.

Instances of the first metal lines 104 may optionally be located under the resistor heads 122 and/or under the resistor body 126, as depicted in FIG. 1. Locating instances of the first metal lines 104 under the thin film resistor 120 may advantageously reduce a size of the integrated circuit 100.

The second ILD layer 130 is disposed over the thin film resistor 120, and the dielectric layer 114. The second ILD layer 130 may have a composition and thickness similar to the first ILD layer 102. A plurality of second vias 134 having copper damascene structures are disposed in the second ILD layer 130. Some of the second vias 134 extend through the dielectric layer 114 and make connections to the first metal lines 104. One or more of the second vias 134 makes a connection to each resistor head 122. Each instance of the second vias 134 includes a refractory metal liner 136 of tantalum and/or tantalum nitride, and a fill metal 138 of copper. The second vias 134 may be part of dual damascene structures which include second metal lines 140 over the second vias 134, as depicted in FIG. 1. Alternatively, the second vias 134 may be single damascene structures. The integrated circuit 100 includes an etch stop layer 142 over the second ILD layer 130, and possibly a third ILD layer 144 over the etch stop layer 142. Using instances of the second vias 134 to connect to the resistor heads 122, which is enabled by forming the resistor heads 122 in the dielectric layer 114, may advantageously reduce complexity and cost of the integrated circuit 100.

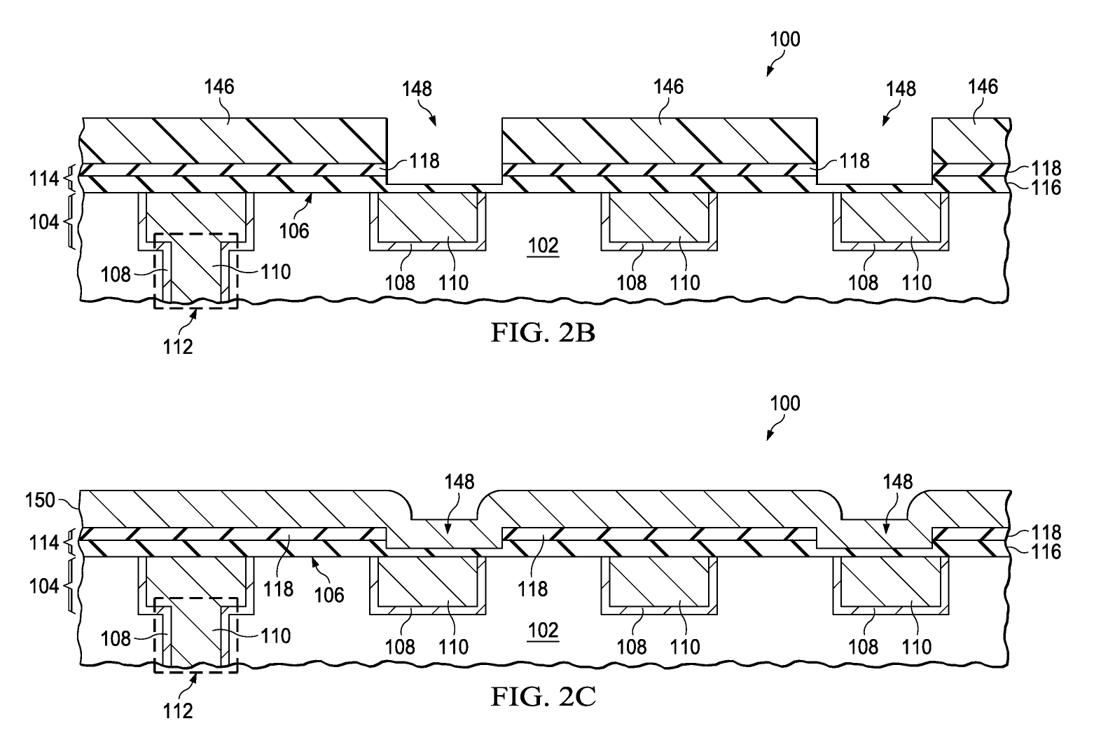

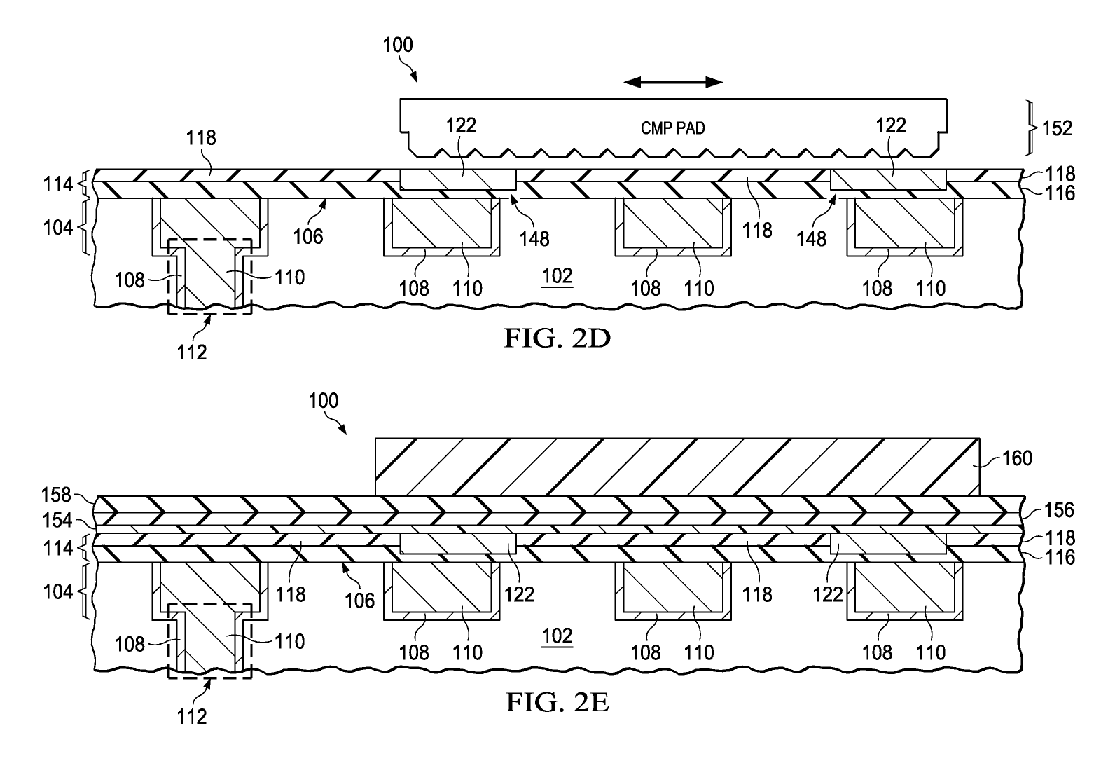

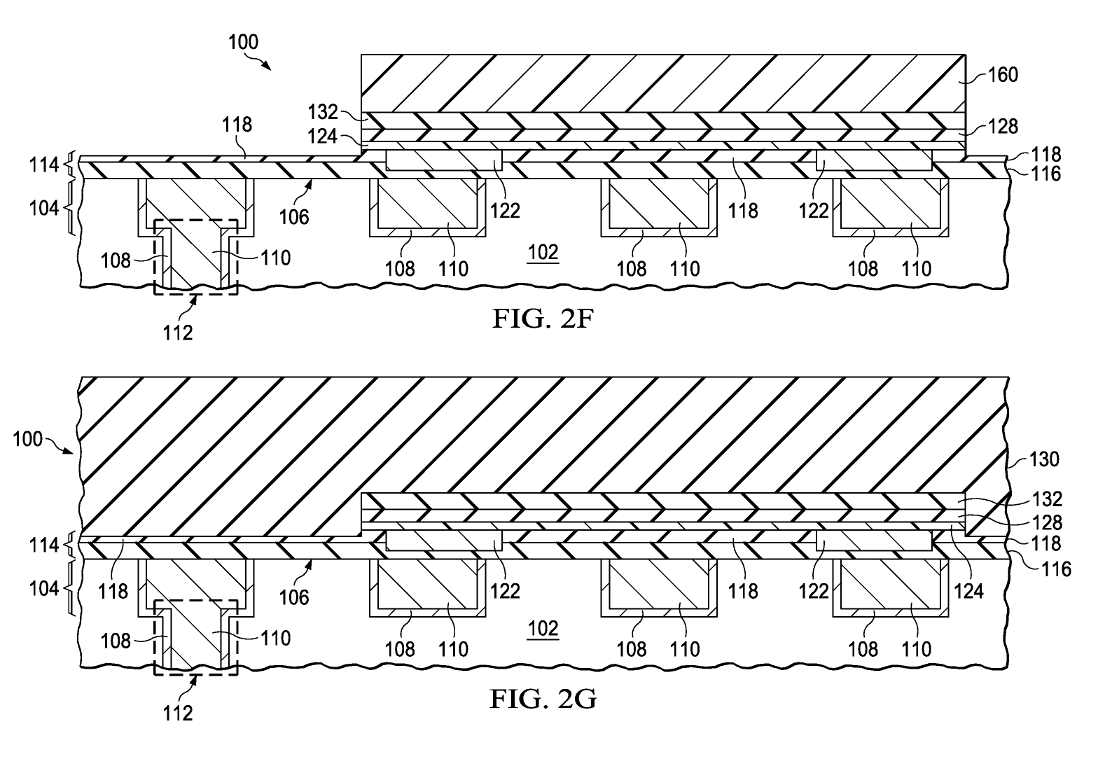

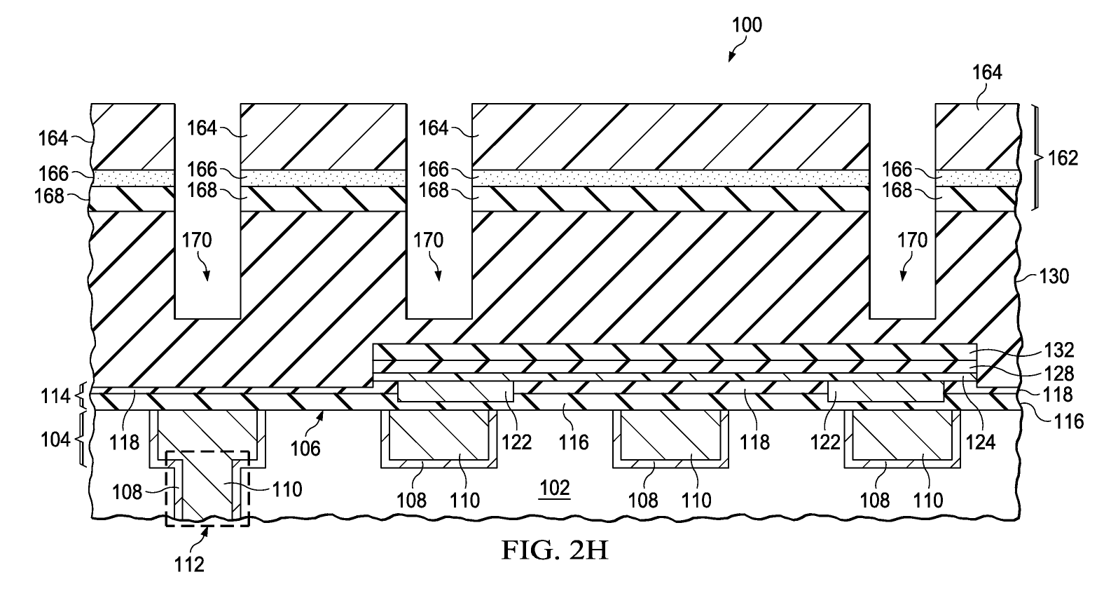

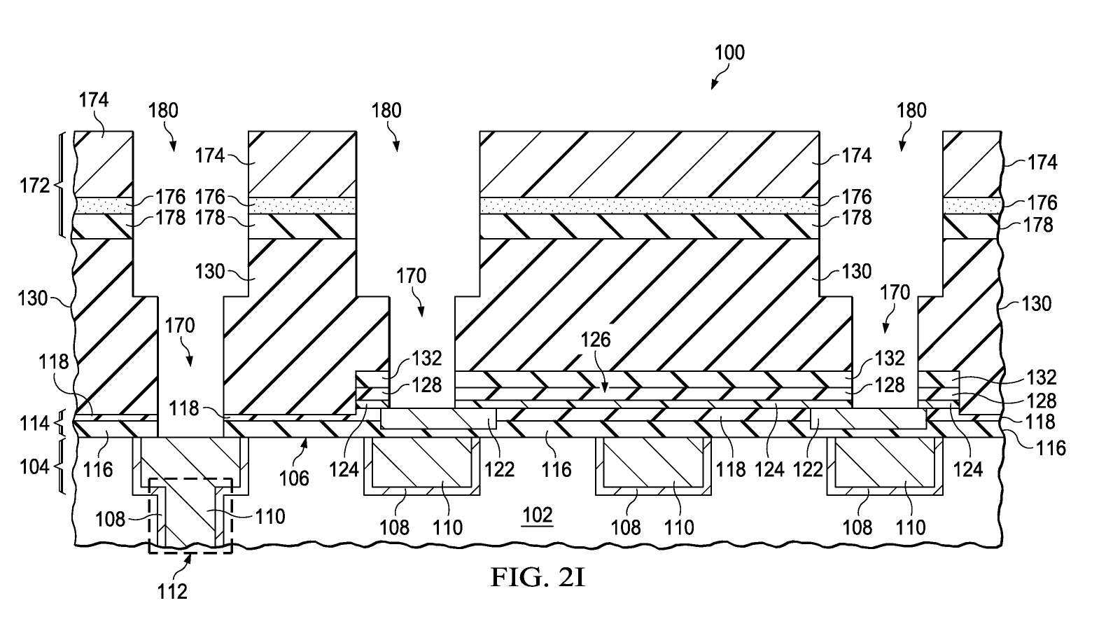

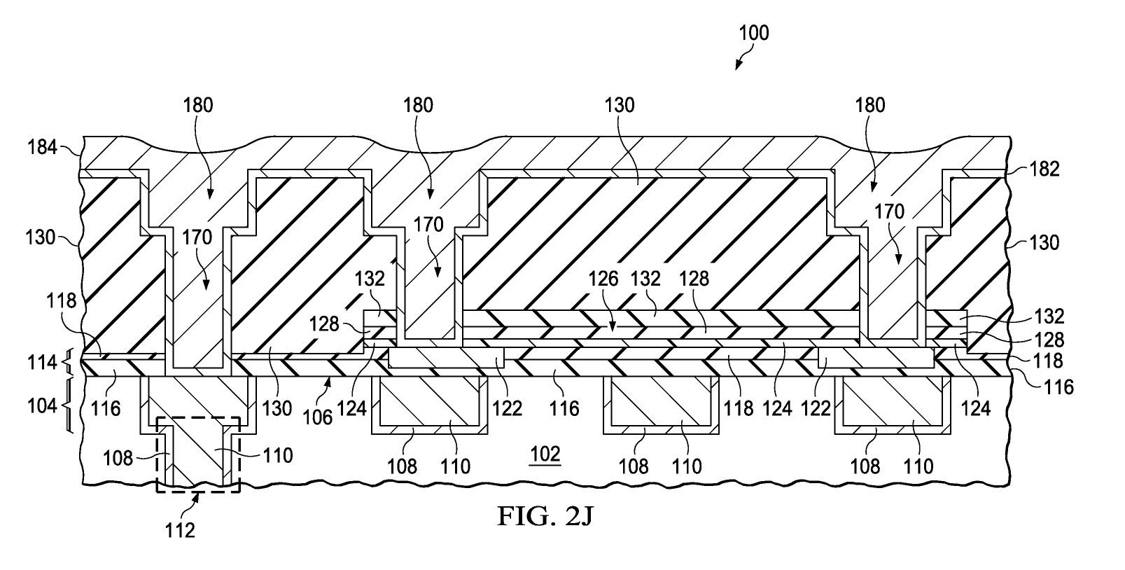

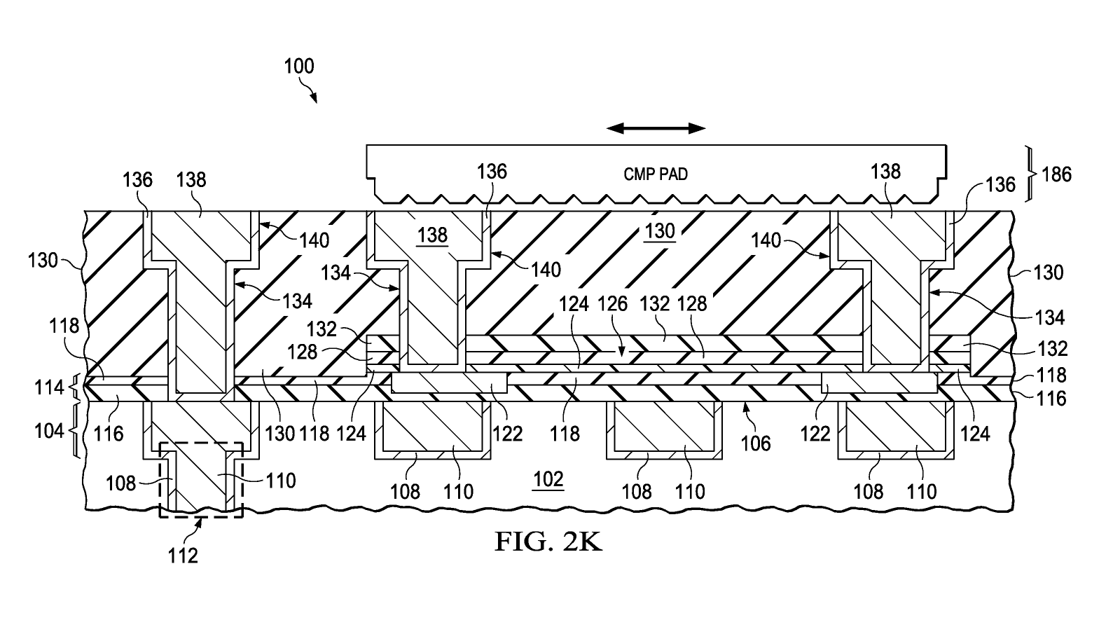

FIG. 2A through FIG. 2K are cross sections of the integrated circuit of FIG. 1 depicted in successive stages of fabrication. Referring to FIG. 2A, the first ILD layer 102 is formed over lower layers and a substrate of the integrated circuit 100. The first ILD layer 102 may include FSG, OSG or other silicon dioxide-based dielectric material, formed by plasma enhanced chemical vapor deposition (PECVD) or other suitable process. The first ILD layer 102 may include an optional cap layer of silicon nitride, not shown, formed by PECVD or other material suitable for a stop layer for a copper chemical mechanical polish (CMP) process. The first metal lines 104 are formed in the first ILD layer 102 by a copper damascene process, which includes etching trenches in the first ILD layer 102, forming the metal liner 108 in the trenches and over the first ILD layer 102 by sputtering, reactive sputtering and/or atomic layer deposition (ALD), forming the copper fill metal 110 on the metal liner 108 in the trenches and over the first ILD layer 102 by sputtering a copper seed layer followed by electroplating copper, and subsequently removing the copper fill metal 110 and the metal liner 108 from over the first ILD layer 102 by a copper CMP process. As discussed in reference to FIG. 1, the first metal lines 104 may be formed by a dual damascene process which also forms the first vias 112 so that the first vias 112 and the first metal lines 104 both include the metal liner 108 and the copper fill metal 110.

The dielectric layer 114 is formed on the first ILD layer 102 and on the first metal lines 104. The dielectric layer 114 may include one or more sub-layers. One such sub-layer is the etch stop layer 116. The etch stop layer 116 includes silicon nitride and is formed by PECVD using silane, ammonia and nitrogen gases, to provide desired etch selectivity to subsequently-formed overlying layers of silicon dioxide-based dielectric materials. In the instant example, the dielectric layer 114 includes the resistor backside passivation layer 118, which includes silicon dioxide formed by PECVD using tetraethyl orthosilicate, also known as tetraethoxysilane (TEOS). A thickness of the resistor backside passivation layer 118 at formation may be selected to account for material loss during subsequent formation of the resistor heads 122 of FIG. 1.

A resistor head mask 146 is formed over the dielectric layer 114 so as to expose the dielectric layer 114 in areas for the resistor heads 122 of FIG. 1. The resistor head mask 146 may include photoresist formed by a photolithographic process, and may possibly include an anti-reflection layer and/or a hard mask layer.

Referring to FIG. 2B, the resistor backside passivation layer 118, and possibly a portion of the etch stop layer 116 as depicted in FIG. 2B, is removed in the areas exposed by the resistor head mask 146. The resistor backside passivation layer 118 and the portion of the etch stop layer 116 may be removed by a reactive ion etch (RIE) process using fluorine radicals, possibly followed by an optional wet etch using a buffered dilute aqueous solution of hydrofluoric acid, to form resistor head cavities 148 in the dielectric layer 114. In an alternate version of the instant example, only a negligible amount of the etch stop layer 116 may be removed, so that the resistor head cavities 148 extend only through the resistor backside passivation layer 118. In another example, in which there are no instances of the first metal lines 104 located directly under the resistor heads 122 of FIG. 1, the resistor head cavities 148 may extend completely through the dielectric layer 114. In a further example, there may be instances of the first metal lines 104 confined to areas under the resistor heads 122 which are not connected to instances of the first vias 112, so as to provide etch stop elements for the resistor head formation process. In such an example, the resistor head cavities 148 extend to the underlying instances of the first metal lines 104. The resistor head mask 146 is subsequently removed, for example by an ash process.

Referring to FIG. 2C, a layer of refractory metal 150 is formed over the dielectric layer 114, extending into and filling the resistor head cavities 148. The layer of refractory metal 150 may include a layer of tantalum formed by sputtering and/or a layer of tantalum nitride formed by reactive sputtering or ALD. The layer of refractory metal 150 may have a layer structure and composition similar to the metal liner 108 of the first metal lines 104; the layer of refractory metal 150 may be more than twice as thick as the metal liner 108 so as to fill the resistor head cavities 148.

Referring to FIG. 2D, the layer of refractory metal 150 of FIG. 2C outside of the resistor head cavities 148 is removed, for example by a CMP process 152, leaving the layer of refractory metal 150 in the resistor head cavities 148 to provide the resistor heads 122. Edges of the resistor heads 122 are substantially coplanar with the adjacent dielectric layer 114.

Referring to FIG. 2E, a layer of resistor material 154 is formed on the dielectric layer 114 and the resistor heads 122. The layer of resistor material 154 may include, for example, silicon chromium formed by sputtering, silicon carbon chromium formed by reactive sputtering, and/or nickel chromium, formed by sputtering. Other thin film resistor materials in the layer of resistor material 154 are within the scope of the instant example. The layer of resistor material 154 is less than 15 nanometers thick, and may be, for example, 2 nanometers to 5 nanometers thick. Forming the resistor heads 122 by the CMP process reduces topography under the layer of resistor material 154 at a boundary between the resistor heads 122 and the dielectric layer 114, advantageously providing consistent resistance in the thin film resistor 120 of FIG. 1.

An optional layer of passivation material 156 may be formed on the layer of resistor material 154. The layer of passivation material 156 may include silicon dioxide-based material such as silicon dioxide formed by PECVD using TEOS. The layer of passivation material 156 may have a composition similar to the resistor backside passivation layer 118 if present, which may advantageously enhance electrical performance of the thin film resistor 120. The layer of passivation material 156 may be thinner than the resistor backside passivation layer 118, for example 5 nanometers to 15 nanometers thick, as discussed in reference to the resistor topside passivation layer 128 of FIG. 1. An optional layer of etch stop material 158 may be formed over the layer of resistor material 154, and over the layer of passivation material 156 if present. The layer of etch stop material 158 may include silicon nitride formed by PECVD using silane, ammonia and hydrogen gases, similar to the etch stop layer 116, or may include other dielectric material with suitable etch selectivity to the subsequently-formed second ILD layer 130 of FIG. 1.

A resistor mask 160 is formed over the layer of resistor material 154, and over the layer of passivation material 156 and the layer of etch stop material 158, if present. The resistor mask 160 covers an area for the thin film resistor layer 124 of FIG. 1. The resistor mask 160 may include photoresist formed by a photolithographic process, and may optionally include an anti-reflection layer and/or a hard mask layer.

Referring to FIG. 2F, the layer of resistor material 154 of FIG. 2E, and the layer of passivation material 156 and the layer of etch stop material 158, if present, are removed where exposed by the resistor mask 160, to form the thin film resistor layer 124, the resistor topside passivation layer 128 and the resistor etch stop 132. The layer of resistor material 154, the layer of passivation material 156 and the layer of etch stop material 158 may be removed by a sequence of RIE steps with etch chemistries of each RIE step selected to remove the desired layer with selectivity to the underlying layer. A portion of the dielectric layer 114 may be removed as part of an overetch step when the layer of resistor material 154 is removed, as depicted in FIG. 2F. The resistor mask 160 is subsequently removed, for example by an ash process, followed by a wet clean process using an aqueous mixture of sulfuric acid and hydrogen peroxide, and/or a dilute aqueous mixture of ammonium hydroxide and hydrogen peroxide and/or an organic solvent.

Referring to FIG. 2G, the second ILD layer 130 is formed over the dielectric layer 114 and the thin film resistor layer 124, and the resistor topside passivation layer 128 and the resistor etch stop 132 if present. The second ILD layer 130 may include FSG, OSG or other silicon dioxide-based dielectric material formed by PECVD, and may have a composition and layer structure similar to the first ILD layer 102.

Referring to FIG. 2H, a via mask 162 is formed over the second ILD layer 130 which exposes areas for the second vias 134 of FIG. 1. The via mask 162 may include a photoresist layer 164 formed by a photolithographic process, and may optionally include an anti-reflection layer 166 of organic material or silicon nitride and/or a hard mask layer 168 of amorphous carbon.

Dielectric material of the second ILD layer 130 is removed in the areas exposed by the via mask 162 to form partial via holes 170 in the second ILD layer 130. In the instant example, which describes a partial-via-first dual damascene process, the partial via holes 170 do not extend all the way to the first metal lines 104 or to the resistor heads 122. The via mask 162 is subsequently removed. Photoresist, organic material and amorphous carbon in the via mask 162 may be removed by an ash process and an organic solvent wet clean process. Inorganic material such as silicon nitride in the via mask 162 may be removed by plasma etching. The partial via holes 170 may be filled with organic material to prevent deformation during a subsequent process to form interconnect trenches.

Referring to FIG. 2I, a trench mask 172 is formed over the second ILD layer 130 which exposes area for the second metal lines 140 of FIG. 1. The trench mask 172 may include a photoresist layer 174, and may optionally include an anti-reflection layer 176 and/or a hard mask layer 178. Dielectric material of the second ILD layer 130 is removed in the areas exposed by the trench mask 172 to form trenches 180 over the via holes 170, and dielectric material of the second ILD layer 130 is removed in the via holes to extend the via holes 170 to the etch stop layer 116 over the first metal lines 104 and to the resistor etch stop 132 over the resistor heads 122. The dielectric material of the second ILD layer 130 may be removed using an RIE process with an etch chemistry appropriate for etching silicon dioxide-based material, with selectivity to the etch stop layer 116 and the resistor etch stop 132. Subsequently, dielectric material of the etch stop layer 116 at bottoms of the via holes 170 over the first metal lines 104 and dielectric material of the resistor etch stop 132, the resistor backside passivation layer 118 and the thin film resistor layer 124 at bottoms of the via holes 170 over the resistor heads 122 is removed by an RIE process using a different etch chemistry, so as to expose the second metal lines 140 and the resistor heads 122. The trench mask 172 is removed, for example as described in reference to the via mask 162 of FIG. 2H. In one version of the instant example, the trench mask 172 may be removed after the etch stop layer 116 and the resistor etch stop 132 are removed in the via holes 170 as depicted in FIG. 2I. In an alternate version of the instant example, the trench mask 172 may be removed before all of the etch stop layer 116 and the resistor etch stop 132 are removed in the via holes 170, and the remaining etch stop layer 116 and the resistor etch stop 132 are removed by a blanket etch process, so as to advantageously reduce exposure of the copper fill metal 110 to ambient atmosphere before subsequent formation of liner metal in the via holes 170.

Referring to FIG. 2J, a layer of metal liner 182 is formed on the second ILD layer 130, extending into the trenches 180 and via holes 170 so as to make connections to the first metal lines 104 and the resistor heads 122. The layer of liner metal 182 may include a layer of tantalum formed by sputtering and/or a layer of tantalum nitride formed by reactive sputtering or ALD. The layer of metal liner 182 may have a composition and layer structure similar to the metal liner 108 of the first metal lines 104. A fill metal 184 of copper is formed on the layer of metal liner 182, extending into the trenches 180 and via holes 170. The fill metal 184 may be formed by sputtering a seed layer of copper onto the layer of metal liner 182 and electroplating copper on the seed layer.

Referring to FIG. 2K, the fill metal 184 and the layer of metal liner 182 of FIG. 2J over a top surface of the second ILD layer 130 are removed by a copper CMP process 186 to form the second vias 134 and the second metal lines 140. Forming the instances of the second vias 134 contacting the resistor heads 122 concurrently with the instances of the second vias 134 contacting the first metal lines 104 may advantageously reduce fabrication cost and complexity of the integrated circuit 100 compared to an integrated circuit with separately-formed vias to the resistor and underlying metal lines. Fabrication of the integrated circuit 100 is continued to provide the structure of FIG. 1.

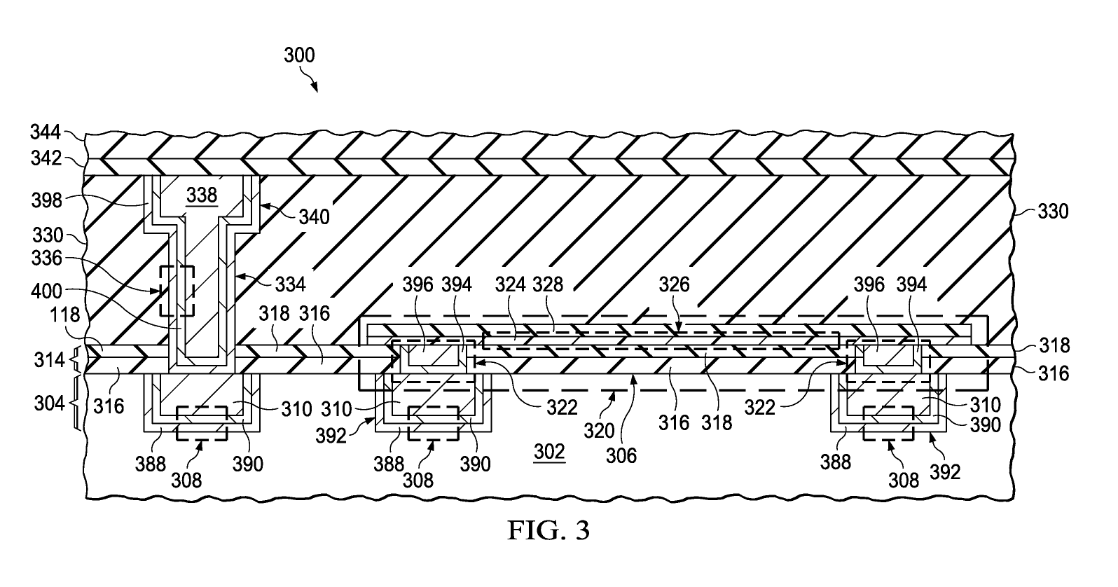

FIG. 3 is a cross section of another example integrated circuit containing a thin film resistor. The integrated circuit 300 includes a first ILD layer 302 of silicon dioxide-based dielectric material. A plurality of first metal lines 304 having copper damascene structures are disposed in the first ILD layer 302, extending to a top surface 306 of the first ILD layer 302. Each instance of the first metal lines 304 includes a refractory metal liner 308. In the instant example, the metal liner 308 includes a first sub-layer 388 of tantalum contacting the first ILD layer 302 and a second sub-layer 390 of tantalum nitride on the first sub-layer 388. Each instance of the first metal lines 304 includes a fill metal 310 of copper on the metal liner 308. In the instant example, the plurality of first metal lines 304 includes resistor connection lines 392 which provide connections to the thin film resistor. The plurality of first metal lines 304 includes other metal lines 304 which are not resistor connection lines 392. The first metal lines 304 may be single damascene structures as depicted in FIG. 3, or may be dual damascene structures which include copper damascene vias. The first metal lines 304 may be in a first interconnect level of the integrated circuit 300, or may be in a higher interconnect level, such as a second interconnect level, a third interconnect level, and so forth.

A dielectric layer 314 is disposed on the first ILD layer 302 and on the first metal lines 304. The dielectric layer 314 is less than 200 nanometers thick. The dielectric layer 314 includes an etch stop layer 316 over the first metal lines 304. The etch stop layer 316 may be silicon nitride-based dielectric material, 35 nanometers to 100 nanometers thick. The dielectric layer 314 may include a resistor backside passivation layer 318 over the etch stop layer 316. The resistor backside passivation layer 318 may be silicon dioxide-based dielectric material, 15 nanometers to 100 nanometers thick, which advantageously provides desired adhesion and electrical properties for the thin film resistor 320.

Resistor heads 322 of the thin film resistor 320 are disposed in the dielectric layer 314, so that edges of the resistor heads 322 are substantially coplanar with the adjacent dielectric layer 314. The resistor heads 322 comprise refractory metal; in the instant example, the resistor heads 322 include a first sub-layer 394 of tantalum contacting the dielectric layer 314 and a second sub-layer 396 of tantalum nitride on the first sub-layer 394, similar to the metal liner 308 of the first metal lines 304. Other structures of refractory metal for the resistor heads 322 are within the scope of the instant example. The resistor heads 322 extend through the dielectric layer 314 and make electrical connections to the resistor connection lines 392.

A thin film resistor layer 324 is disposed on the dielectric layer 314, extending onto the resistor heads 322. The thin film resistor layer 324 between the resistor heads 322 provides a resistor body 326 of the thin film resistor 320. The thin film resistor layer 324 may include any appropriate thin film resistor material, as described in reference to FIG. 1. The thin film resistor layer 324 is less than 15 nanometers thick. The thin film resistor layer 324 may cover the resistor heads 322 as depicted in FIG. 3 or may extend only partway onto the resistor heads 322.

An optional resistor topside passivation layer 328 may be disposed on the thin film resistor layer 324. The resistor topside passivation layer 328 is a dielectric sub-layer and may have a composition similar to the resistor backside passivation layer 318 which advantageously enhances electrical performance of the thin film resistor 320. The resistor topside passivation layer 328 may be thinner than the resistor backside passivation layer 318, for example 5 nanometers to 15 nanometers thick.

A second ILD layer 330 is disposed over the dielectric layer 314 and the thin film resistor 320. The second ILD layer 330 may have a composition and thickness similar to the first ILD layer 302. At least one via 334 having a copper damascene structure is disposed in the second ILD layer 330, extending through the dielectric layer 314 and making an electrical connection to an instance of the first metal lines 304. The via 334 may be one of a plurality of vias 334. Each instance of the vias 334 includes a refractory metal liner 336 of tantalum and/or tantalum nitride, and a fill metal 338 of copper. In the instant example, the metal liner 336 includes a first sub-layer 398 of tantalum contacting the first ILD layer 302 and a second sub-layer 400 of tantalum nitride on the first sub-layer 388. Each instance of the vias 334 includes a fill metal 338 of copper on the metal liner 336. The second vias 334 may be part of dual damascene structures which include second metal lines 340 over the second vias 334, as depicted in FIG. 3. Alternatively, the second vias 334 may be single damascene structures.

The integrated circuit 300 includes an etch stop layer 342 over the second ILD layer 330, and possibly a third ILD layer 344 over the etch stop layer 342. Using instances of the first metal lines 304 to connect to the resistor heads 322, which is enabled by forming the resistor heads 322 in the dielectric layer 314, may advantageously reduce complexity and cost of the integrated circuit 300.

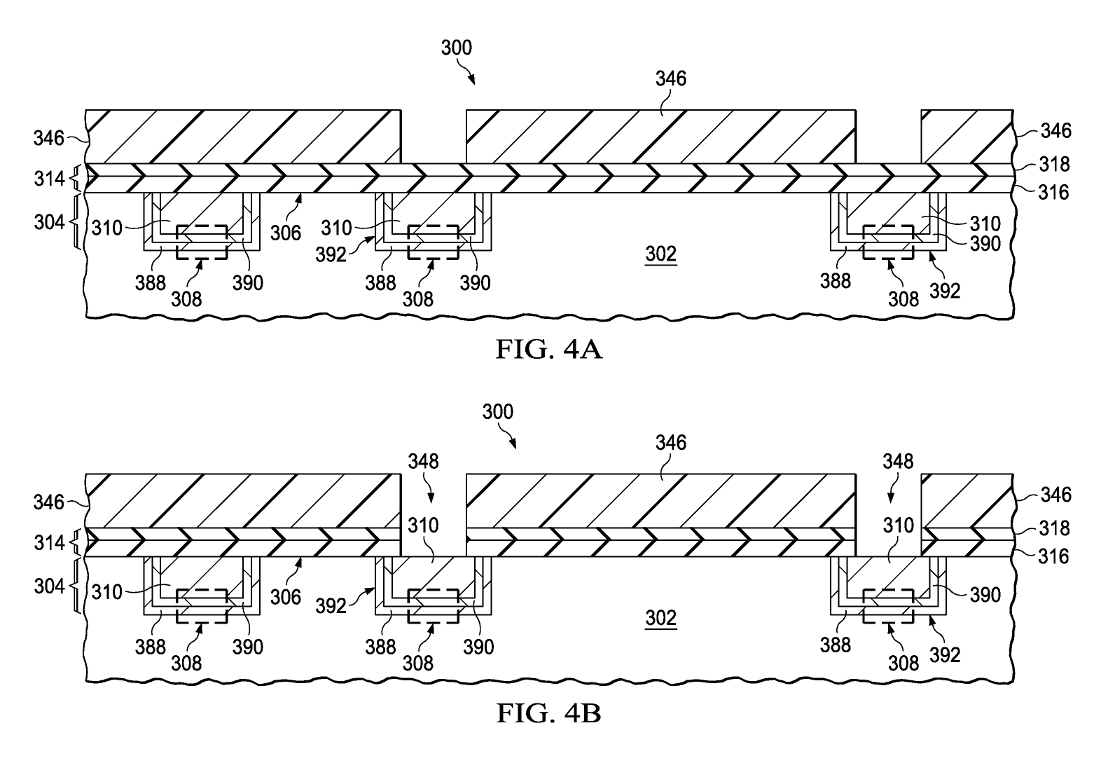

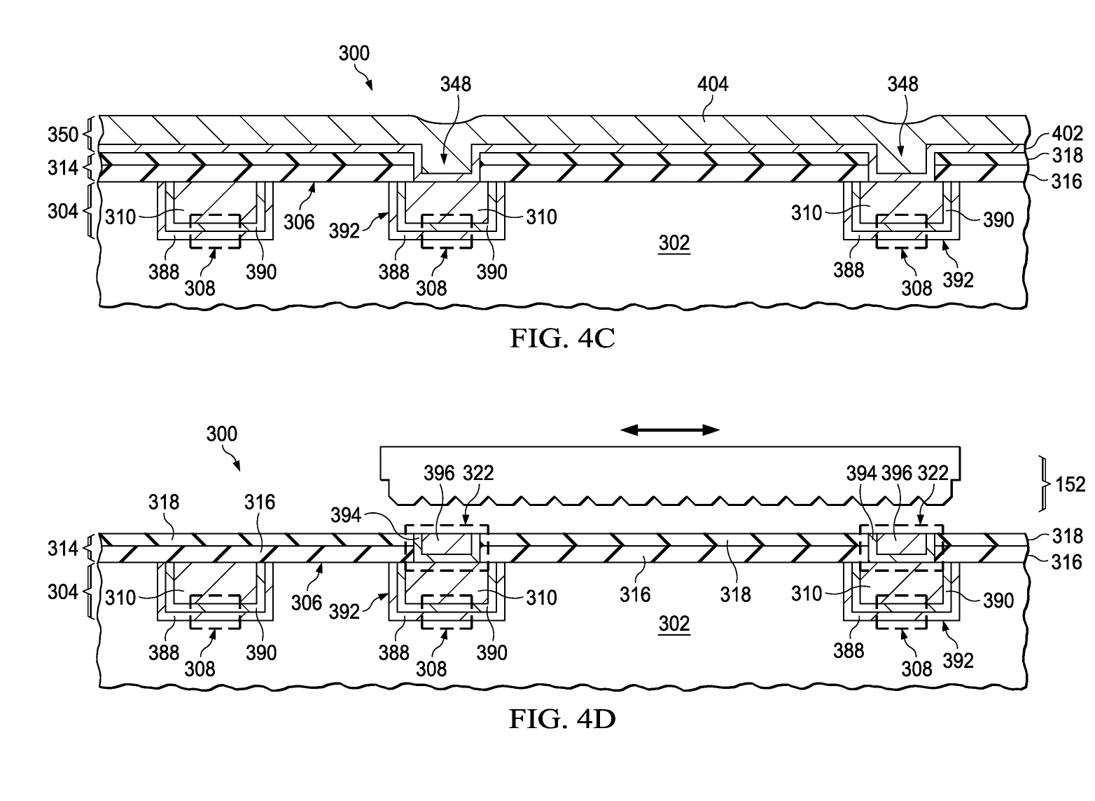

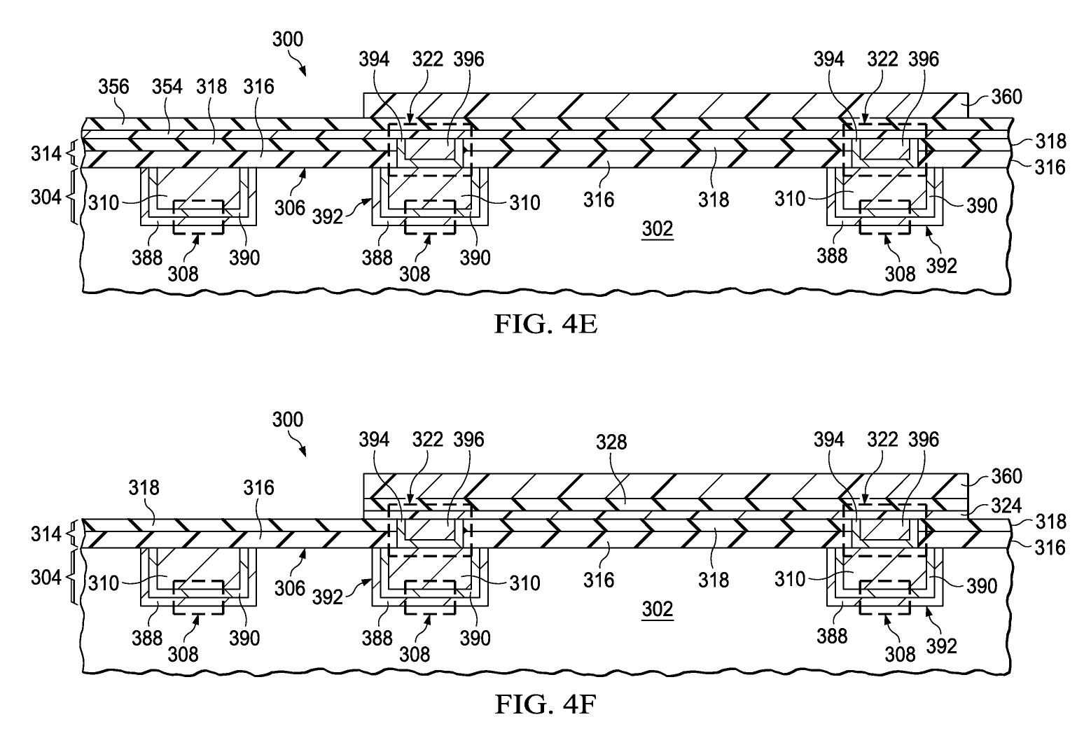

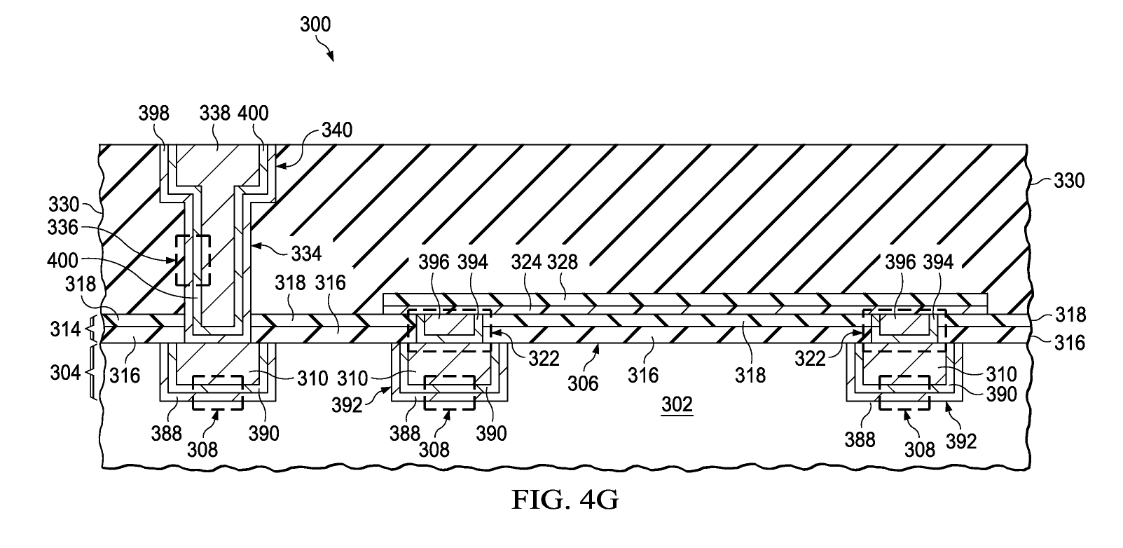

FIG. 4A through FIG. 4G are cross sections of the integrated circuit of FIG. 3 depicted in successive stages of fabrication. Referring to FIG. 4A, the first ILD layer 302 is formed over lower layers and a substrate of the integrated circuit 300. The first ILD layer 302 may include FSG, OSG or other silicon dioxide-based dielectric material, formed by PECVD or other suitable process. The first ILD layer 302 may include an optional cap layer of silicon nitride, not shown. The first metal lines 304 are formed in the first ILD layer 302 by a copper damascene process, which includes etching trenches in the first ILD layer 302, forming the metal liner 308 in the trenches and over the first ILD layer 302 by sputtering tantalum for the first sub-layer 388 and depositing tantalum nitride by reactive sputtering or ALD for the second sub-layer 390, forming the copper fill metal 310 on the metal liner 308 in the trenches and over the first ILD layer 302 by sputtering a copper seed layer followed by electroplating copper, and subsequently removing the copper fill metal 310 and the metal liner 308 from over the first ILD layer 302 by a copper CMP process. As discussed in reference to FIG. 3, the first metal lines 304 may be formed by a dual damascene process which also forms vias so that the vias and the first metal lines 304 both include the metal liner 308 and the copper fill metal 310.

The dielectric layer 314 is formed on the first ILD layer 302 and on the first metal lines 304. The etch stop layer 316 includes silicon nitride and is formed by PECVD using silane, ammonia and nitrogen gases. In the instant example, the dielectric layer 314 includes the resistor backside passivation layer 318, which includes silicon dioxide formed by PECVD using TEOS. A thickness of the resistor backside passivation layer 318 may be selected to account for material loss during subsequent formation of the resistor heads 312 of FIG. 3.

A resistor head mask 346 is formed over the dielectric layer 314 so as to expose the dielectric layer 314 in areas for the resistor heads 322 of FIG. 3, over the resistor connection lines 392. The resistor head mask 346 may include photoresist formed by a photolithographic process, and may possibly include an anti-reflection layer and/or a hard mask layer. The resistor head mask 346 may be thicker than the resistor head mask 146 of FIG. 2A, as the resistor head mask 346 of the instant example has to provide acceptable masking functionality during removal of the complete etch stop layer 316 in the areas exposed by the resistor head mask 346.

Referring to FIG. 4B, the resistor backside passivation layer 318 and the etch stop layer 316 are removed in the areas exposed by the resistor head mask 346 to form resistor head cavities 348. The resistor backside passivation layer 318 and the portion of the etch stop layer 316 may be removed by a sequence of RIE processes appropriate for the compositions of the layers of the dielectric layer 314. The resistor connection lines 392 are exposed. The resistor head mask 346 is removed, for example by an ash process and an organic solvent wet clean process. In one version of the instant example, the resistor head mask 346 may be removed after all of the etch stop layer 316 in the resistor head cavities 348 is removed, as depicted in FIG. 4B. In an alternate version, the resistor head mask 346 may be removed before all of the etch stop layer 316 in the resistor head cavities 348 is removed, and the remaining etch stop layer 316 in the resistor head cavities 348 is removed by a blanket etch process, so as to advantageously reduce exposure of the copper fill metal 310 to ambient atmosphere before subsequent formation of resistor head metal in the resistor head cavities 348.

Referring to FIG. 4C, a layer of refractory metal 350 is formed over the dielectric layer 314, extending into and filling the resistor head cavities 348. In the instant example, the layer of refractory metal 350 includes a first layer 402 of tantalum, formed by sputtering, contacting the resistor connection lines 392 and the dielectric layer 314, and a second layer 404 of tantalum nitride, formed by ALD or reactive sputtering, on the first layer 402. The layer of refractory metal 350 may have a layer structure and composition similar to the metal liner 308 of the first metal lines 304; the layer of refractory metal 350 may be more than twice as thick as the metal liner 308 so as to fill the resistor head cavities 348. Other layer structures and compositions for the layer of refractory metal 350 are within the scope of the instant example.

Referring to FIG. 4D, the layer of refractory metal 350 of FIG. 4C outside of the resistor head cavities 348 is removed, for example by a CMP process 352, leaving the layer of refractory metal 350 in the resistor head cavities 348 to provide the resistor heads 322. In the instant example, the resistor heads 322 include a first sub-layer 394 of tantalum from the first layer 402 of the layer of refractory metal 350 of FIG. 4C and a second sub-layer 396 of tantalum nitride from the second layer 404 of the layer of refractory metal 350. Edges of the resistor heads 322 are substantially coplanar with the adjacent dielectric layer 314.

Referring to FIG. 4E, a layer of resistor material 354 is formed on the dielectric layer 314 and the resistor heads 322. The layer of resistor material 354 may include any appropriate thin film resistor material. The layer of resistor material 354 is less than 15 nanometers thick, and may be, for example, 2 nanometers to 5 nanometers thick. Forming the resistor heads 322 by the CMP process reduces topography under the layer of resistor material 354 at a boundary between the resistor heads 322 and the dielectric layer 314, advantageously providing consistent resistance in the thin film resistor 320 of FIG. 3.

An optional layer of passivation material 356 may be formed on the layer of resistor material 354. The layer of passivation material 356 may include silicon dioxide-based material. The layer of passivation material 356 may have a composition similar to the resistor backside passivation layer 318 if present, which may advantageously enhance electrical performance of the thin film resistor 320. The layer of passivation material 356 may be thinner than the resistor backside passivation layer 318, for example 5 nanometers to 15 nanometers thick.

A resistor mask 360 is formed over the layer of resistor material 354, and over the layer of passivation material 356 if present. The resistor mask 360 covers an area for the thin film resistor layer 324 of FIG. 1. The resistor mask 360 may include photoresist formed by a photolithographic process, and may optionally include an anti-reflection layer and/or a hard mask layer.

Referring to FIG. 4F, the layer of resistor material 354 of FIG. 4E, and the layer of passivation material 356 of FIG. 4E if present, are removed where exposed by the resistor mask 360 to form the thin film resistor layer 324 and the resistor topside passivation layer 328. The layer of resistor material 354 and the layer of passivation material 356 may be removed by a sequence of RIE steps with etch chemistries of each RIE step selected to remove the desired layer with selectivity to the underlying layer. The resistor mask 360 is subsequently removed, as described in reference to FIG. 2F.

Referring to FIG. 4G, the second ILD layer 330 is formed over the dielectric layer 314 and the thin film resistor layer 324, and over the resistor topside passivation layer 328 if present. The second ILD layer 330 may include FSG, OSG or other silicon dioxide-based dielectric material formed by PECVD, and may have a composition and layer structure similar to the first ILD layer 302.

The at least one via 334 and the second metal line 340 are formed through the second ILD layer 330 to make electrical connection to an instance of the first metal lines 304. The via 334 and the second metal line 340 are formed by a copper dual damascene process. In the instant example, no instances of the vias 334 are formed on the resistor heads 322. Fabrication of the integrated circuit 300 is continued to provide the structure of FIG. 3.

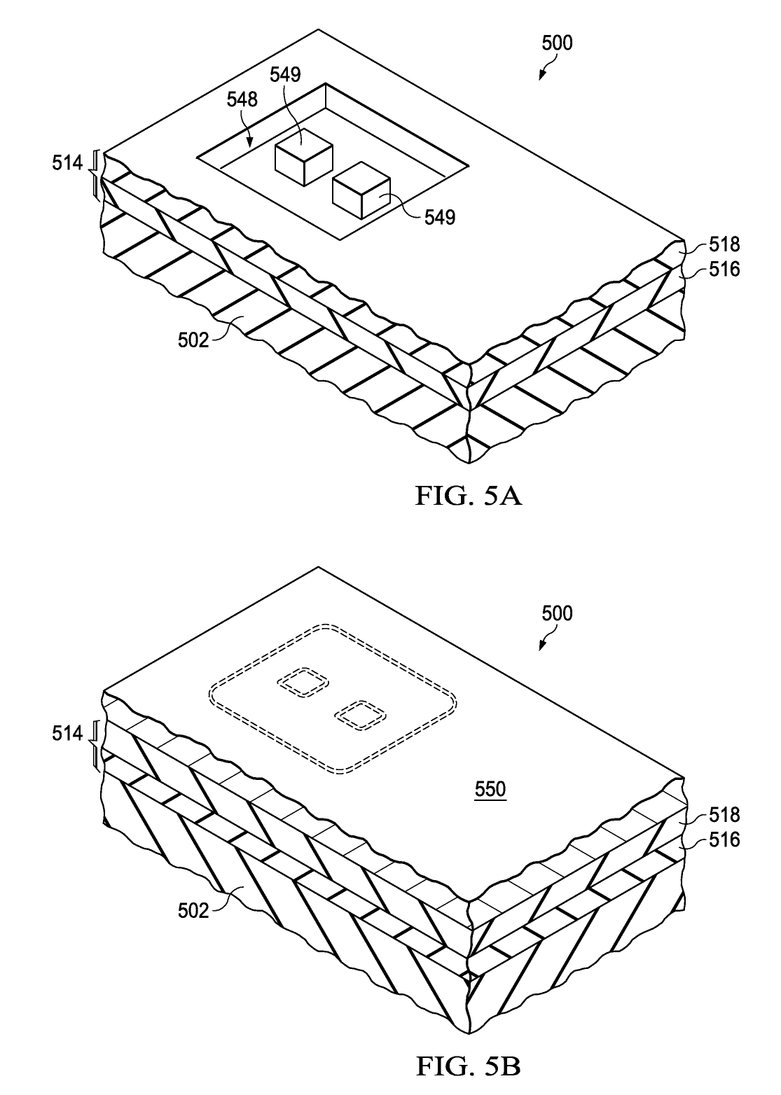

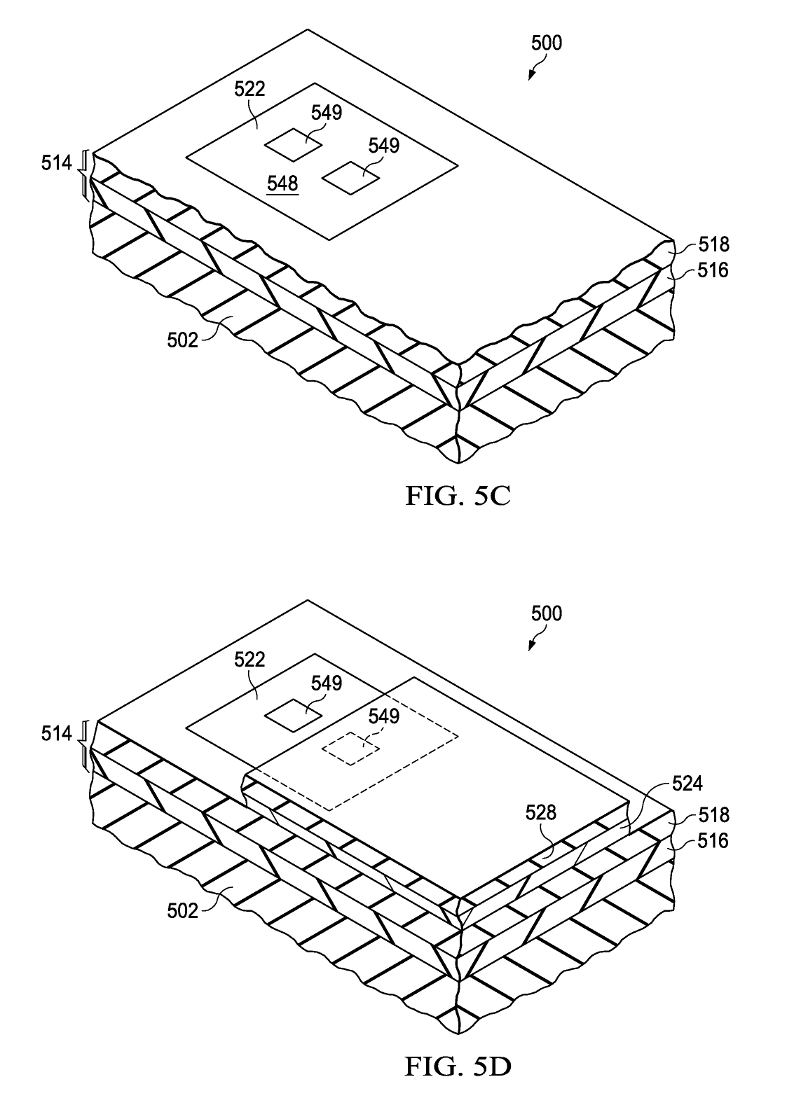

FIG. 5A through FIG. 5D are cross sections of another example integrated circuit containing a thin film resistor, depicted in successive stages of fabrication. Referring to FIG. 5A, the integrated circuit 500 includes a first ILD layer 502 of silicon dioxide-based dielectric material. Metal lines, not shown in FIG. 5A, are formed in the first ILD layer 502 by a copper damascene process. A dielectric layer 514 less than 300 nanometers thick is formed over the first ILD layer 502. The dielectric layer 514 includes an etch stop layer 516 formed on the first ILD layer 502. The etch stop layer 516 may be silicon nitride-based dielectric material, 35 nanometers to 100 nanometers thick. In the instant example, the dielectric layer 514 includes a resistor backside passivation layer 518 formed over the etch stop layer 516. The resistor backside passivation layer 518 may be silicon dioxide-based dielectric material, 45 nanometers to 100 nanometers thick. A plurality of resistor head cavities 548 is formed in the dielectric layer 514; one of the resistor head cavities is depicted in FIG. 5A. In the instant example, the resistor head cavities 548 are formed to extend completely through the resistor backside passivation layer 518 and terminate at the etch stop layer 516. Other configurations of the resistor head cavities 548, for example as described in reference to other example herein, are within the scope of the instant example. At least one of the resistor head cavities 548 is formed so as to leave material from the dielectric layer 514 inside an outer boundary of the resistor head cavity 548 to provide one or more support structures 549 surrounded by the resistor head cavity 548. Top surfaces of the support structures 549 are substantially coplanar with a top surface of the adjacent dielectric layer 514. The resistor head cavity 548 and the support structures 549 may be formed by forming a resistor head mask over the dielectric layer which exposes an area for the resistor head cavity 548 and covers areas for the support structures 549, then removing material from the dielectric layer 514 in the area exposed by the resistor head mask, and subsequently removing the resistor head mask.

Referring to FIG. 5B, a layer of refractory metal 550 is formed over the dielectric layer 514, extending into and filling the resistor head cavities 548 of FIG. 5A. The support structures 549 of FIG. 5A provide a top surface of the layer of refractory metal 550 over the resistor head cavity 548 that is more planar than a corresponding resistor head cavity with no anti-dishing structures.

Referring to FIG. 5C, the layer of refractory metal 550 of FIG. 5B is removed from over the top surface of the dielectric layer 514 by a CMP process, leaving refractory material in the resistor head cavity 548 to provide a resistor head 522. The remaining dielectric layer 514 is less than 200 nanometers thick. Forming the support structures 549 provides support for a CMP pad during polishing which results in a top surface of the resistor head 522 which is more planar than a corresponding resistor head with no anti-dishing structures. The greater planarity of the top surface of the resistor head 522 may advantageously provide lower, and more consistent, contact resistance to a subsequently-formed via making an electrical connection to the resistor head 522.

Referring to FIG. 5D, a thin film resistor layer 524 is formed on the dielectric layer 514, extending onto, and making electrical contact to, the resistor head 522. The thin film resistor layer 524 may extend partway onto the resistor head 522 as depicted in FIG. 5D, which may advantageously reduce a size of the integrated circuit 500. A topside resistor passivation layer 528 may be formed over the thin film resistor layer 524. A resistor etch stop, not shown in FIG. 5D, may be formed over the thin film resistor layer 524. Fabrication of the integrated circuit 500 continues with formation of a second ILD layer and vias in the second ILD layer.

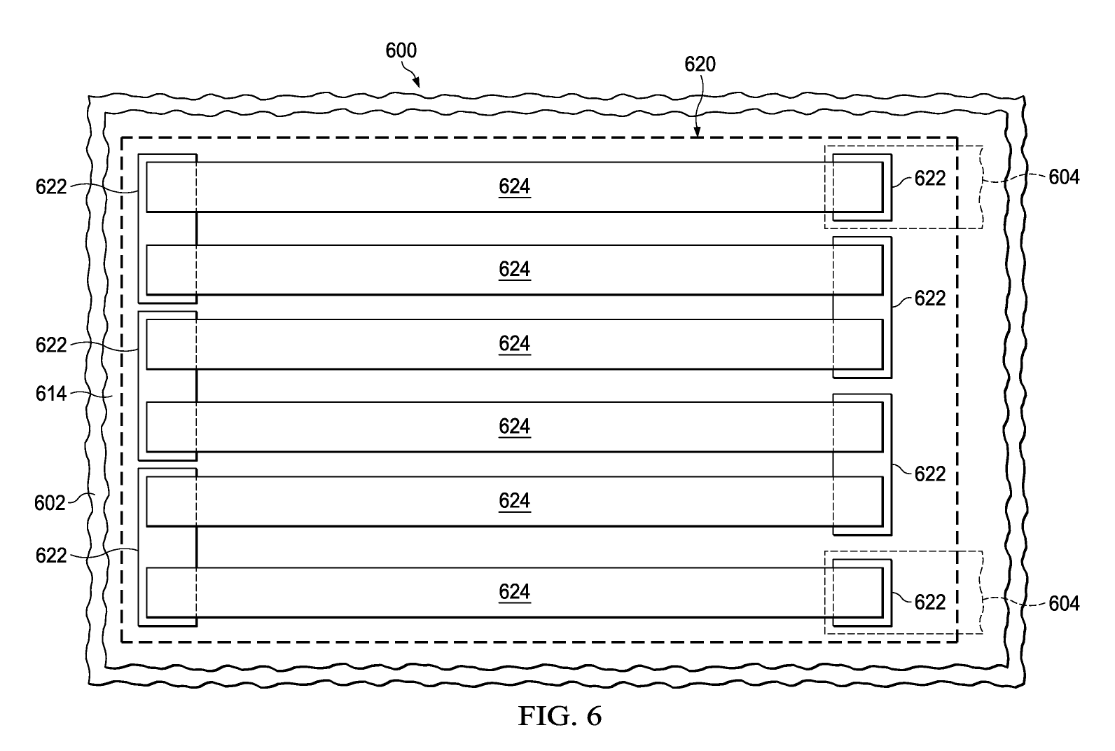

FIG. 6 is a top view of an example integrated circuit containing a thin film resistor. The integrated circuit 600 includes a first ILD layer 602 of silicon dioxide-based dielectric material. Metal lines 604 are formed in the first ILD layer 602 by a copper damascene process. A dielectric layer 614 less than 200 nanometers thick is disposed over the first ILD layer 602. The dielectric layer 614 includes an etch stop layer formed on the first ILD layer 602. A plurality of resistor heads 622 is formed in the dielectric layer 614 in a ladder configuration. The resistor heads 622 are formed of refractory metal by a damascene process. Edges of the resistor heads 622 are substantially coplanar with the adjacent dielectric layer 614. A plurality of thin film resistor layers 624 are formed in the ladder configuration on the dielectric layer 614, extending onto the resistor heads 622 to form the thin film resistor 620. At least one of the resistor heads 622 underlies two of the thin film resistor layers 624 and is free of a connection to the metal lines 604. The ladder configuration may provide a desired consistency of total resistance of the thin film resistor 620. Forming the resistor heads 622 in the dielectric layer 614 may advantageously reduce a size of the thin film resistor 620 compared to ladder configuration thin film resistors with interconnects such as metal lines or vias at each resistor head. In another version of the instant example, electrical connections to the resistor heads 622 may be made by vias having copper damascene structures in a second ILD layer over the dielectric layer 614.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. An integrated circuit, comprising:
a first inter-level dielectric (ILD) layer;
a plurality of metal lines having copper damascene structures disposed in the first ILD layer, extending to a top surface of the first ILD layer;
a dielectric layer less than 200 nanometers thick disposed on the first ILD layer and on the first metal lines, the dielectric layer comprising an etch stop layer;
a second ILD layer disposed over the dielectric layer;
a plurality of vias having copper damascene structures disposed in the second ILD layer, wherein instances of the vias make connections to instances of the metal lines; and
a thin film resistor, comprising:
resistor heads disposed in the dielectric layer, wherein edges of the resistor heads are substantially coplanar with the adjacent dielectric layer; and
a thin film resistor layer less than 15 nanometers thick disposed on the dielectric layer and extending onto the resistor heads;
wherein electrical connections to the resistor heads are made by interconnects selected from the group consisting of the metal lines and the vias.

2. The integrated circuit of claim 1, wherein the dielectric layer comprises a resistor backside passivation layer disposed over the etch stop layer, the resistor backside passivation layer comprising silicon dioxide-based dielectric material.

3. The integrated circuit of claim 1, comprising a resistor topside passivation layer disposed over thin film resistor layer, not extending substantially past the thin film resistor layer, the resistor topside passivation layer comprising silicon dioxide-based dielectric material.

4. The integrated circuit of claim 1, comprising a resistor etch stop disposed over thin film resistor layer, not extending substantially past the thin film resistor layer.

5. The integrated circuit of claim 1, wherein the resistor heads have a layer structure and composition similar to metal liners of the metal lines.

6. The integrated circuit of claim 1, wherein the resistor heads comprise material selected from the group consisting of tantalum and tantalum nitride.

7. The integrated circuit of claim 1, wherein the thin film resistor layer extends past the resistor heads on all sides.

8. The integrated circuit of claim 1, wherein the thin film resistor layer extends partway onto the resistor heads and does not cover the resistor heads.

9. The integrated circuit of claim 1, wherein at least one of the resistor heads has a support structure of dielectric material of the dielectric layer surrounded by the at least one resistor head, the support structure extending to a top surface of the at least one resistor head.

10. The integrated circuit of claim 1, wherein the thin film resistor layer has a ladder configuration, wherein:
the thin film resistor layer is a first thin film resistor layer;
the thin film resistor comprises a second thin film resistor layer; and
the first thin film resistor layer and the second thin film resistor layer extend onto an instance of the resistor heads which is free of a connection to the metal lines and free of a connection to the vias.

11. A method of forming an integrated circuit, comprising the steps:
forming a first ILD layer;
forming a plurality of metal lines in the first ILD layer by a copper damascene process so that the metal lines extend to a top surface of the first ILD layer;
forming a dielectric layer on the first ILD layer, the dielectric layer comprising an etch stop layer;
forming a resistor head mask over the dielectric layer which exposes areas for resistor heads;
removing dielectric material from the dielectric layer in the areas exposed by the resistor head mask to form resistor head cavities in the dielectric layer;
removing the resistor head mask;
forming a layer of refractory metal over the dielectric layer, extending into the resistor head cavities;
removing the layer of refractory metal from outside the resistor head cavities to form resistor heads so that edges of the resistor heads are substantially coplanar with the adjacent dielectric layer, wherein the adjacent dielectric layer is less than 200 nanometers thick;
forming a layer of resistor material less than 15 nanometers thick on the dielectric layer and the resistor heads;
patterning the layer of resistor material to form a thin film resistor layer extending onto the resistor heads;
forming a second ILD layer over the dielectric layer and the thin film resistor layer; and
forming a plurality of vias in the second ILD layer by a copper damascene process so that instances of the vias make connections to instances of the metal lines;
wherein electrical connections to the resistor heads are made by interconnects selected from the group consisting of the metal lines and the vias.

12. The method of claim 11, wherein forming the dielectric layer comprises forming a resistor backside passivation layer disposed over the etch stop layer, the resistor backside passivation layer comprising silicon dioxide-based dielectric material.

13. The method of claim 11, comprising forming a layer of passivation material on the layer of resistor material, the layer of passivation material comprising silicon dioxide-based dielectric material, prior to patterning the layer of resistor material.

14. The method of claim 11, comprising forming a layer of etch stop material over the layer of resistor material, prior to patterning the layer of resistor material.

15. The method of claim 11, wherein the resistor heads have a layer structure and composition similar to metal liners of the metal lines.

16. The method of claim 11, wherein the layer of refractory metal comprises material selected from the group consisting of tantalum and tantalum nitride.

17. The method of claim 11, wherein patterning the layer of resistor material results in the thin film resistor layer extending past the resistor heads on all sides.

18. The method of claim 11, wherein patterning the layer of resistor material results in the thin film resistor layer extending partway onto the resistor heads so that a portion of the resistor heads is free of the thin film resistor layer.

19. The method of claim 11, wherein:
the resistor head mask covers an area for a support structure in the area for one of the resistor heads; and
the step of removing the dielectric material from the dielectric layer in the areas exposed by the resistor head mask leaves dielectric material in the area for the support structure, so that a top surface of the support structure is substantially coplanar with a top surface of the adjacent dielectric layer.

20. The method of claim 11, wherein removing the layer of refractory metal from outside the resistor head cavities is performed by a chemical mechanical polish (CMP) process.
